(19) United States
(12) Patent Application Publication
(10) Pub. No.: US 2020/0087780 A1
(43) Pub. Date: Mar. 19, 2020

(54) CLAMPING DEVICE, MANUFACTURING APPARATUS FOR EL DEVICE, CONTROLLER, AND MANUFACTURING METHOD FOR EL DEVICE

(71) Applicant: Sharp Kabushiki Kaisha, Sakai City, Osaka (JP)

(72) Inventor: Tomoaki KURATATE, Sakai City (JP)

(21) Appl. No.: 16/463,027

(22) PCT Filed: Jun. 7, 2017
(86) PCT No.: PCT/JP2017/021132

§ 371 Date: May 22, 2019

(51) Int. Cl. C23C 14/50; H05B 33/10; H01L 33/00; H01L 51/00; H01L 51/56; C23C 14/04

(52) U.S. Cl. CPC C23C 14/505; H05B 33/10; C23C 14/042; H01L 51/0011; H01L 51/56; H01L 33/005

(57) ABSTRACT

A clamping device includes a first clamping member including a main rotating member rotatable around a main rotating shaft provided on a first end side of an evaporation mask to face a support member across the evaporation mask, the main rotating member including an auxiliary rotating shaft, and the first clamping member further including an auxiliary rotating member rotatable around the auxiliary rotating shaft to come into surface-contact with a second surface of the evaporation mask.

### TECHNICAL FIELD

The disclosure relates to a clamping device for clamping an evaporation mask placed on a substrate, a manufacturing apparatus for an EL device, a controller, and a manufacturing method for an EL device.

### BACKGROUND ART

In the related art, there is known a clamping device for clamping an evaporation mask placed on a substrate in order to form a deposition layer for an electro luminescence (EL) device (Patent Literature 1). The clamping device includes a holding part for holding opposing two sides of the evaporation mask and a driving member for pulling each holding part to stretch (apply tension to) the evaporation mask. Then, with the tension applied to the evaporation mask, the evaporation mask is aligned with the substrate and fixed.

### CITATION LIST

### Patent Literature

PTL1: JP 2015-28204 A (published on Feb. 12, 2015)

### SUMMARY

### Technical Problem

However, in a case where the holding part holding the evaporation mask is pulled by the driving member to stretch the evaporation mask, the evaporation mask slips from the holding part, causing positional deviation of the evaporation mask with respect to the substrate and bending of the evaporation mask. As a result, stretching conditions of the evaporation mask are deviated, and at the time of stretching the evaporation mask, the evaporation mask is deviated to an unintended position and clamped there.

### Solution to Problem

A clamping device in accordance with an aspect of the disclosure includes: a first clamping member configured to clamp a first end of an evaporation mask placed on a substrate; and a second clamping member configured to clamp a second end of the evaporation mask, the first clamping member including: a support member configured to support a first surface of the evaporation mask; and a main rotating member rotatable around a main rotating shaft provided on a side of the first end of the evaporation mask to face the support member across the evaporation mask, the main rotating member including an auxiliary rotating shaft, and the first clamping member further including an auxiliary rotating member rotatable around the auxiliary rotating shaft to come into surface-contact with a second surface of the evaporation mask.

### Advantageous Effects of Disclosure

According to an aspect of the disclosure, deviation of a clamp position of an evaporation mask can be prevented.

### BRIEF DESCRIPTION OF DRAWINGS

FIG. 1 is a plan view of a clamping device according to a first embodiment of the disclosure.

FIG. 2 is a cross-sectional view taken along the plane AA of FIG. 1.

FIG. 3 is a front view of a first clamping member provided in the clamping device.

FIG. 4 is a front view illustrating the behavior of the first clamping member.

FIGS. 5A to 5E illustrate a positional relationship between an auxiliary rotating shaft of an auxiliary rotating member provided on the first clamping member and a contact surface.

FIG. 6 is a front view of a first clamping member provided in a clamping device according to a second embodiment of the disclosure.

FIG. 7 is a schematic view for illustrating an amount of movement of a main rotating member and an auxiliary rotating member provided in the first clamping member.

FIG. 8 is a diagram for illustrating a deviation amount dₐ of the main rotating member.

FIGS. 9A to 9C are views for illustrating a deviation amount d_{c} of the auxiliary rotating member.

### DESCRIPTION OF EMBODIMENTS

### First Embodiment

Configuration of Clamping Device 1

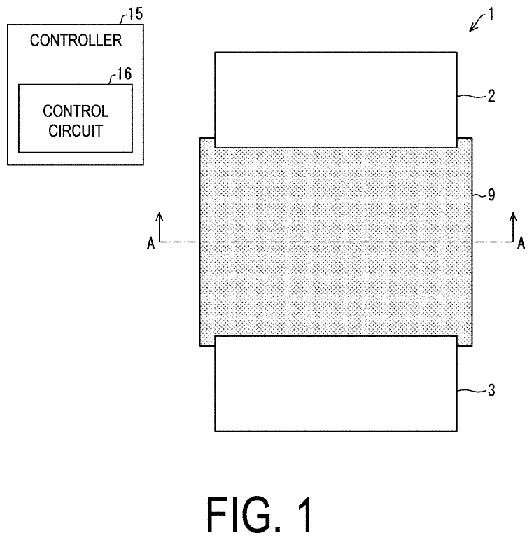

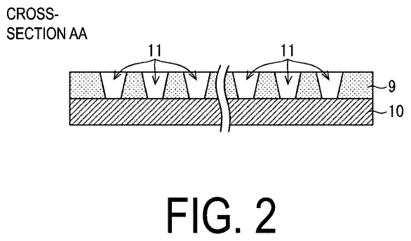

FIG. 1 is a plan view of a clamping device 1 according to a first embodiment of the disclosure. FIG. 2 is a cross-sectional view taken along the plane AA of FIG. 1. In order to form a deposition layer for an EL device, the clamping device 1 includes a first clamping member 2 for clamping a first end of an evaporation mask 9 placed on a substrate 10 and a second clamping member 3 for clamping a second end of the evaporation mask 9. In the evaporation mask 9, a plurality of slits 11 are formed in order to form a deposition layer corresponding to a subpixel of the EL device on the substrate 10. The evaporation mask 9 has a dimension of a thickness of 20 μm and a side length of 1000 mm, for example, and is formed of metal. The first clamping member 2 and the second clamping member 3 are made of metal.

The substrate 10 on which the EL device is formed may constitute a flexible display. The flexible display device is not particularly limited to a specific display device, as long as it is a display panel that has flexibility and is provided with bendable optical elements. The optical element is an optical element whose luminance and transmittance are controlled by an electric current, and examples of the electric current-controlled optical element include an organic Electro Luminescence (EL) display provided with an Organic Light Emitting Diode (OLED), an EL display such as an inorganic EL display provided with an inorganic light emitting diode, or a QLED display provided with a Quantum Dot Light Emitting Diode (QLED).

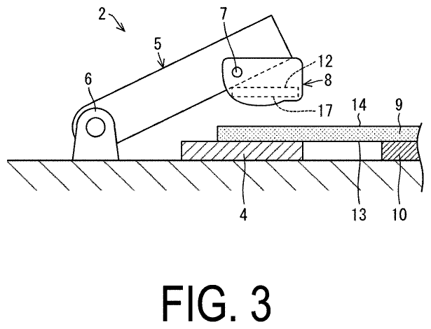

FIG. 3 is a front view of the first clamping member 2 provided in the clamping device 1. The first clamping member 2 has a support member 4 for supporting a side of a first end of a rear surface 13 (first surface) of the evaporation mask 9, and a main rotating member 5 that is rotatable around a main rotating shaft 6 provided on the side of the first end of the evaporation mask 9 to face the support member 4 across with the evaporation mask 9. A auxiliary rotating shaft 7 is provided parallel to the main rotating shaft 6 on a distal end side of the main rotating member 5.

The first clamping member 2 has an auxiliary rotating member 8 that is rotatable around the auxiliary rotating shaft 7 to come into surface-contact with a surface 14 (second surface) of the evaporation mask 9. The auxiliary rotating member 8 has a contact portion 12 having a contact surface 17 that comes into surface-contact with the surface 14 of the evaporation mask 9.

A controller 15 having a control circuit 16 for controlling behaviors of the main rotating member 5 and the auxiliary rotating member 8, is provided in the clamping device 1.

### Behavior of Clamping Device 1

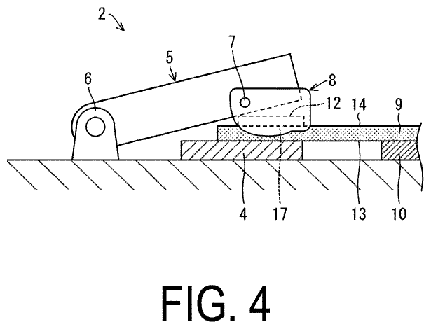

FIG. 4 is a front view illustrating the behavior of the first clamping member 2. When the main rotating member 5 arranged to face the support member 4 across the evaporation mask 9 rotates in the clockwise direction around the main rotating shaft 6, the auxiliary rotating member 8 provided on the distal end side of the main rotating member 5 approaches the surface 14 of the evaporation mask 9. Then, one end of a contact surface 17 positioned on the side, the side facing the evaporation mask 9, of the contact portion 12 provided on the auxiliary rotating member 8, is in contact with the surface 14 of the evaporation mask 9. After that, as the main rotating member 5 further rotates in the clockwise direction, the auxiliary rotating member 8 rotates in the counterclockwise direction around the auxiliary rotating shaft 7. As a result, as illustrated in FIG. 4, the contact surface 17 of the contact portion 12 of the auxiliary rotating member 8 is brought into close contact with the surface 14 of the evaporation mask 9 by surface-contact. In this manner, the main rotating member 5 and the auxiliary rotating member 8 sandwich the evaporation mask 9 with the support member 4.

At this time, by properly selecting a weight balance between the auxiliary rotating member 8 and the auxiliary rotating shaft 7 of the auxiliary rotating member 8, a structure around the auxiliary rotating shaft 7 of the auxiliary rotating member 8 may be ensured, by which, in accordance with rotation of the main rotating member 5, the auxiliary rotating member 8 can start on a contact point with the evaporation mask 9, approaching the evaporation mask. Thus, the auxiliary rotating member 8 first comes into point-contact with the evaporation mask 9 and then comes into surface-contact therewith, without providing the auxiliary rotating shaft 7 with a mechanically driving mechanism.

FIGS. SA to 5E illustrate a positional relationship between the auxiliary rotating shaft 7 of the auxiliary rotating member 8 provided on the first clamping member 2 and the contact surface 17. Here, described are possible surface-contact forms of the contact surface 17.

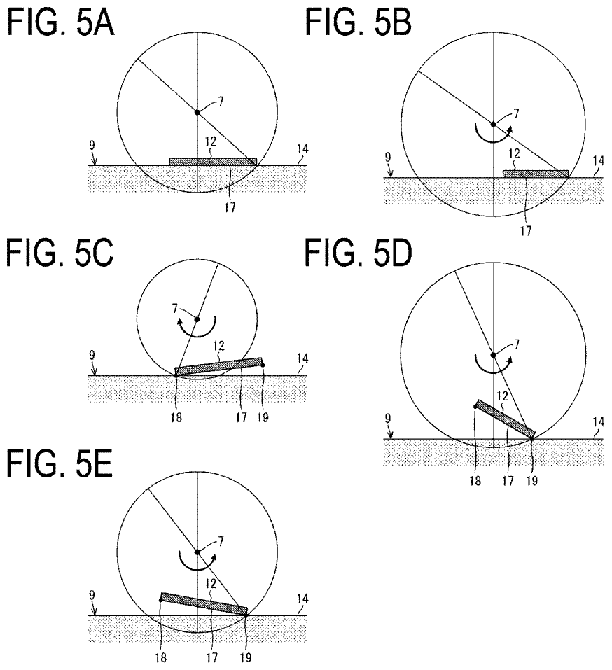

Referring to FIG. 5A, in a process in which the main rotating member 5 rotates in the clockwise direction around the main rotating shaft 6 and then approaches the evaporation mask 9, even in a case where the contact portion 12 causes the contact surface 17 to first come into surface-contact with the evaporation mask 9, the rotational moment of the contact portion 12 is rarely generated around the auxiliary rotating shaft 7 in the course of applying a force to the evaporation mask 9 by the contact portion 12.

Referring to FIG. 5B, in a process in which the main rotating member 5 rotates in the clockwise direction around the main rotating shaft 6 and then approaches the evaporation mask 9, even in a case where the contact portion 12 causes the contact surface 17 to first come into surface-contact with the evaporation mask 9, and the rotational moment of the contact portion 12 is generated around the auxiliary rotating shaft 7 in the process of applying the force to the evaporation mask 9 by the contact portion 12, the surface-contacted state may be maintained by providing the auxiliary rotating member 8 with weights or the like in order to cancel the rotational moment.

Referring to FIG. 5C, in a process in which the main rotating member 5 rotates in the clockwise direction around the main rotating shaft 6 and then approaches the evaporation mask 9, a first end 18 of the contact surface 17 comes into point-contact with the evaporation mask 9. Then, the contact portion 12 of the auxiliary rotating member 8 rotates in the clockwise direction around the auxiliary rotating shaft 7. As a result, the contact portion 12 causes the contact surface 17 to come into surface-contact with the evaporation mask 9.

Referring to FIG. 5D, in a process in which the main rotating member 5 rotates in the clockwise direction around the main rotating shaft 6 and then approaches the evaporation mask 9, a second end 19 of the contact surface 17 comes into point-contact with the evaporation mask 9. Then, the contact portion 12 of the auxiliary rotating member 8 rotates in the counterclockwise direction around the auxiliary rotating shaft 7. As a result, the contact portion 12 causes the contact surface 17 to come into surface-contact with the evaporation mask 9.

Referring to FIG. 5E, in a process in which the main rotating member 5 rotates in the clockwise direction around the main rotating shaft 6 and then approaches the evaporation mask 9, the second end 19 of the contact surface 17 comes into point-contact with the evaporation mask 9. Then, the contact portion 12 of the auxiliary rotating member 8 rotates in the counterclockwise direction around the auxiliary rotating shaft 7. As a result, the contact portion 12 causes the contact surface 17 to come into surface-contact with the evaporation mask 9.

After shifted to the surface-contacted state, the evaporation mask 9 receives a force in the direction perpendicular to the surface 14 thereof and is fixed by the main rotating member 5 and the auxiliary rotating member 8. By thus applying the force in the direction perpendicular to the surface 14 of the evaporation mask 9 instead of applying tension thereto, the evaporation mask 9 is fixed. Therefore, a problem may be overcome that the evaporation mask 9 slips from the holding part for holding the evaporation mask 9 in order to apply tension to the evaporation mask 9, causing positional deviation of the evaporation mask 9 with respect to the substrate or bending of the evaporation mask 9. As a result, positioning accuracy for the evaporation mask can be improved.

By further applying a rotational force by the main rotating member 5 in order to bring the auxiliary rotating member 8 into a close surface-contacted state, a force may be applied in the direction perpendicular to the contact surface 17.

Further, by attaching an electromagnet to the contact portion 12 and powering the electromagnet, in a state in which the contact portion 12 is in a close surface-contacted state to thus generate a magnetic force and then magnetically attract a magnetically attractable mask material, such as an invar material, of the evaporation mask 9, a force may be generated in the direction perpendicular to the surface 14 of the evaporation mask 9 and the contact surface 17.

With the above methods, a pressure is applied to the surface 14 of the evaporation mask 9 and the contact surface 17 of the contact portion 12. This makes it possible to apply a sufficient clamping pressure so that the evaporation mask 9 does not cause positional deviation at the time of stretching the mask.

The second clamping member 3 is preferably configured similarly to the first clamping member 2.

### Second Embodiment

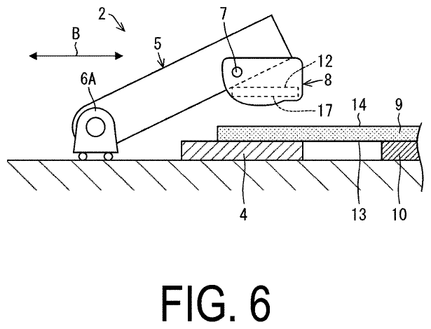

FIG. 6 is a front view of a first clamping member 2A provided in a clamping device according to a second embodiment of the disclosure. In the second embodiment, the same reference numerals are attached to the same components as those of the first embodiment. Thus, detailed descriptions are omitted here.

In the first clamping member 2A, a main rotating shaft 6A is configured to move in a direction of the arrow B along the surface 14 of the evaporation mask 9.

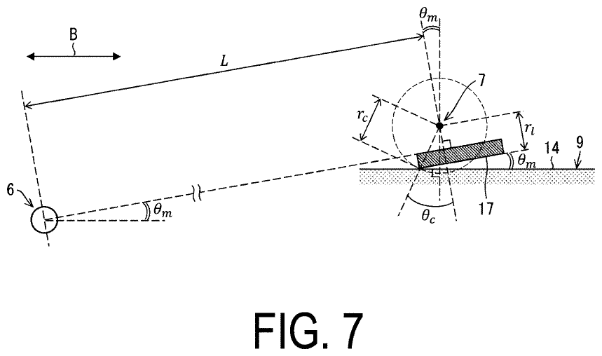

FIG. 7 is a schematic view for explaining the amount of movement of the main rotating member 5 and the auxiliary rotating member 8 provided in the first clamping member 2, 2A.

First, assuming that θₘ indicates a rotational angle, as illustrated in FIG. 7, the rotational angle is an angle by which the main rotating member 5 rotates around the main rotating shaft 6, from a point, at which the main rotating member 5 rotates in the clockwise direction around the main rotating shaft 6 and then one end of the contact surface 17 of the auxiliary rotating member 8 comes into contact with the surface 14 of the evaporation mask 9, to a point, at which the contact surface 17 of the auxiliary rotating member 8 comes into close surface-contact with the surface 14 of the evaporation mask 9.

Further assuming that L indicates a length from the main rotating shaft 6 of the main rotating member 5 to the auxiliary rotating shaft 7, r_{c} indicates a distance between one end of the contact surface 17 being in contact with the surface 14 of the evaporation mask 9 and the auxiliary rotating shaft 7, and r₁ indicates a distance between the contact surface 17 and the auxiliary rotating shaft 7.

Still further assuming that θ_{c} indicates an angle made by a straight line connecting one end of the contact surface 17, being in contact with the surface 14 of the evaporation mask 9, with the auxiliary rotating shaft 7, and a straight line perpendicular to the contact surface 17.

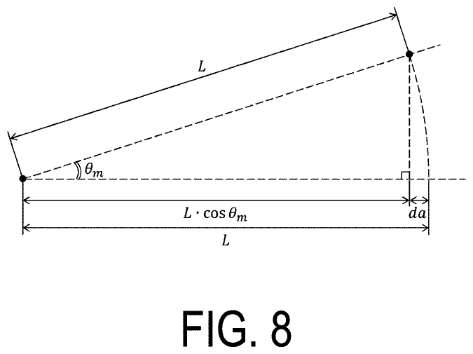

Then, a deviation amount dₐ of the main rotating member 5 in the direction of the arrow B, which is caused by the main rotating member 5 rotating around the main rotating shaft 6 by the angle θₘ, is expressed by Equation 1 below. FIG. 8 is a diagram for explaining the deviation amount dₐ of the main rotating member 5.

[Equation 1]

da=L×(1−cos θₘ) (Math 1)

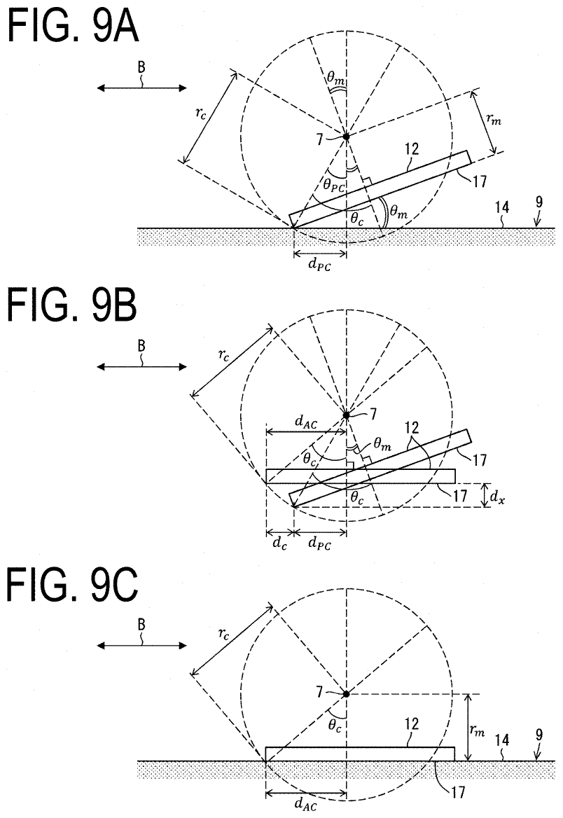

FIGS. 9A to 9C are views for explaining a deviation amount d_{c} of the auxiliary rotating member 8. When a state of FIG. 9A becomes a state of FIG. 9C in which the contact portion 12 with the contact surface 17 rotates in the clockwise direction around the auxiliary rotating shaft 7 by the angle θₘ and then comes into surface-contact with the evaporation mask 9, the contact portion 12 of the auxiliary rotating member 8 is deviated by the deviation amount d_{c} along the direction of the arrow B as illustrated in FIG. 9B. This deviation amount d_{c} is expressed by Equation 2 to Equation 4 below.

$$\begin{matrix}[ Equation 2 ] & \\ \begin{matrix}{d}_{c} = {d}_{A C} - {d}_{PC} \\ = {r}_{c} \times sin {θ}_{c} - {r}_{c} \times sin ( {θ}_{c} - {θ}_{m} ) \\ = {r}_{c} \times \{ sin {θ}_{c} - sin ( {θ}_{c} - {θ}_{m} ) \}\end{matrix} \} \\ [ Equation 3 ] & ( Math 2 ) \\ \begin{matrix}{d}_{PC} = {r}_{c} \times sin ( {θ}_{PC} ) \\ = {r}_{c} \times sin ( {θ}_{c} - {θ}_{m} )\end{matrix} \} \\ [ Equation 4 ] & ( Math 3 ) \\ {d}_{A C} = {r}_{c} \times sin ( {θ}_{c} ) & ( Math 4 )\end{matrix}$$

Note that the contact portion 12 is, as illustrated in FIG. 9B, deviated by a deviation amount dₓ also in the direction perpendicular to the arrow B. However, this deviation amount dₓ is a negligible factor because it does not involve a deviation along the surface 14 of the evaporation mask 9.

From the viewpoint of applying a force in the direction perpendicular to the surface 14 of the evaporation mask 9, a deviation amount (d_{c}+dₐ) is preferably reduced.

Ideally that (d_{c}+dₐ)=0 mm.

In practice, however, preferably that

(d_{c}+dₐ)<1 mm (Math 5).

More preferably,

(d_{c}+dₐ)<0.2 mm (Math 6).

Thus, the length L, the angle θₘ, the distance r_{c}, and the distance r₁ are determined to satisfy the condition of Math 5 or Math 6.

Then, when the main rotating member 5 rotates around the main rotating shaft 6 by the angle θₘ, the main rotating shaft 6 is moved in the direction of the arrow B according to the value of (d_{c}+dₐ). Thus, the evaporation mask 9 can be fixed by applying a force from a direction which is closer to the perpendicular direction to the surface 14 of the evaporation mask 9.

Further, a configuration may be employed that a deviation amount of (d_{c}+dₐ) is first anticipated, and then the evaporation mask 9 is placed being offset by the anticipated deviation amount of (d_{c}+dₐ) and clamped by the first clamping member 2.

The second clamping member 3 is preferably configured similarly to the first clamping member 2.

As described above, the configuration of the second embodiment realizes a reduction in the deviation amount of the clamp position along the direction of the arrow B. Therefore, a problem may be overcome that the evaporation mask 9 slips from the holding part for holding the evaporation mask 9 in order to apply tension to the evaporation mask 9, causing positional deviation of the evaporation mask 9 with respect to the substrate or bending of the evaporation mask 9. As a result, positioning accuracy for the evaporation mask 9 can be improved.

### Supplement

A first aspect of the disclosure provides a clamping device including: a first clamping member configured to clamp a first end of an evaporation mask placed on a substrate; and a second clamping member configured to clamp a second end of the evaporation mask, the first clamping member including: a support member configured to support a first surface of the evaporation mask; and a main rotating member rotatable around a main rotating shaft provided on a side of the first end of the evaporation mask to face the support member across the evaporation mask, the main rotating member including an auxiliary rotating shaft, and the first clamping member further including an auxiliary rotating member rotatable around the auxiliary rotating shaft to come into surface-contact with a second surface of the evaporation mask.

In a second aspect of the disclosure, the clamping device is configured such that the auxiliary rotating member includes a contact surface allowed to come into surface-contact with the second surface of the evaporation mask, the clamping device includes a structure by which, after one end of the contact surface of the auxiliary rotating member comes into contact with the second surface of the evaporation mask in accordance with rotation of the main rotating member, the main rotating member further rotates to allow the auxiliary rotating member to rotate around the auxiliary rotating shaft and then to allow the contact surface of the auxiliary rotating member to come into surface-contact with the second surface of the evaporation mask.

In a third aspect of the disclosure, the clamping device is configured such that the main rotating member rotates around the main rotating shaft in a direction approaching the evaporation mask so that the auxiliary rotating member approaches the evaporation mask and the one end of the contact surface of the auxiliary rotating member comes into contact with the second surface of the evaporation mask.

In a fourth aspect of the disclosure, the clamping device is configured such that the main rotating shaft is configured to move in a direction along a surface of the evaporation mask.

In a fifth aspect of the disclosure, the clamping device is configured such that an evaporation layer for an optical element is formed by deposition on the substrate via the evaporation mask, and the optical element includes an organic light emitting diode, an inorganic light emitting diode, or a quantum dot light-emitting diode.

In a sixth aspect of the disclosure, the clamping device is configured such that the auxiliary rotating member includes an electromagnet configured to, when powered in a state in which the auxiliary rotating member is in surface-contact with the second surface of the evaporation mask, generate a magnetic force causing the auxiliary rotating member to magnetically come into close contact with the evaporation mask.

A seventh aspect of the disclosure provides a manufacturing apparatus for an EL device, including: a first clamping member configured to clamp a first end of an evaporation mask placed on a substrate to form an evaporation layer for the EL device; and a second clamping member configured to clamp a second end of the evaporation mask, the first clamping member including: a support member configured to support a first surface of the evaporation mask; and a main rotating member rotatable around a main rotating shaft provided on a side of the first end of the evaporation mask to face the support member across the evaporation mask, the main rotating member including an auxiliary rotating shaft, the first clamping member further including an auxiliary rotating member rotatable around the auxiliary rotating shaft to come into surface-contact with the second surface of the evaporation mask, and the EL device including an organic light emitting diode, an inorganic light emitting diode, or a quantum dot light-emitting diode.

An eighth aspect of the disclosure provides a controller configured to control the manufacturing apparatus for an EL device according to the seventh aspect, including: a control circuit provided to allow the main rotating member to rotate around the main rotating shaft provided on the first end side of the evaporation mask to face the support member across the evaporation mask.

A ninth aspect of the disclosure provides a manufacturing method for an EL device, the method using a manufacturing apparatus for the EL device including: a first clamping member configured to clamp a first end of an evaporation mask placed on a substrate to form an evaporation layer for the EL device; and a second clamping member configured to clamp a second end of the evaporation mask, the first clamping member including a support member configured to support a first surface of the evaporation mask, the method including: rotating a main rotating member around a main rotating shaft provided on a side of the first end of the evaporation mask to face the support member across the evaporation mask; and rotating an auxiliary rotating member around an auxiliary rotating shaft of the main rotating member to come into surface-contact with the second surface of the evaporation mask, the EL device including an organic light emitting diode, an inorganic light emitting diode, or a quantum dot light-emitting diode.

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Clamping device
2 First clamping member
3 Second clamping member
4 Support member
5 Main rotating member
6 Main rotating shaft
7 Auxiliary rotating shaft
8 Auxiliary rotating member
9 Evaporation mask
10 Substrate
17 Contact surface
15 Controller
16 Control circuit

1. A clamping device comprising:
a first clamping member configured to clamp a first end of an evaporation mask placed on a substrate; and
a second clamping member configured to clamp a second end of the evaporation mask,
the first clamping member including:
a support member configured to support a first surface of the evaporation mask; and
a main rotating member rotatable around a main rotating shaft provided on a side of the first end of the evaporation mask to face the support member across the evaporation mask,
the main rotating member including an auxiliary rotating shaft, and
the first clamping member further including an auxiliary rotating member rotatable around the auxiliary rotating shaft to come into surface-contact with a second surface of the evaporation mask.

2. The clamping device according to claim 1,
wherein the auxiliary rotating member includes a contact surface allowed to come into surface-contact with the second surface of the evaporation mask,
the clamping device comprises a structure by which, after one end of the contact surface of the auxiliary rotating member comes into contact with the second surface of the evaporation mask in accordance with rotation of the main rotating member, the main rotating member further rotates to allow the auxiliary rotating member to rotate around the auxiliary rotating shaft and then to allow the contact surface of the auxiliary rotating member to come into surface-contact with the second surface of the evaporation mask.

3. The clamping device according to claim 2,
wherein the main rotating member rotates around the main rotating shaft in a direction approaching the evaporation mask so that the auxiliary rotating member approaches the evaporation mask and the one end of the contact surface of the auxiliary rotating member comes into contact with the second surface of the evaporation mask.

4. The clamping device according to claim 1,
wherein the main rotating shaft is configured to move in a direction along a surface of the evaporation mask.

5. The clamping device according to claim 1,
wherein an evaporation layer for an optical element is formed by deposition on the substrate via the evaporation mask, and the optical element includes an organic light emitting diode, an inorganic light emitting diode, or a quantum dot light-emitting diode.

6. The clamping device according to claim 1,
wherein the auxiliary rotating member includes an electromagnet configured to, when powered in a state in which the auxiliary rotating member is in surface-contact with the second surface of the evaporation mask, generate a magnetic force causing the auxiliary rotating member to magnetically come into close contact with the evaporation mask.

7. A manufacturing apparatus for an EL device comprising:
a first clamping member configured to clamp a first end of an evaporation mask placed on a substrate to form an evaporation layer for the EL device; and
a second clamping member configured to clamp a second end of the evaporation mask,
the first clamping member including:
a support member configured to support a first surface of the evaporation mask; and
a main rotating member rotatable around a main rotating shaft provided on a side of the first end of the evaporation mask to face the support member across the evaporation mask,
the main rotating member including an auxiliary rotating shaft,
the first clamping member further including an auxiliary rotating member rotatable around the auxiliary rotating shaft to come into surface-contact with a second surface of the evaporation mask, and
the EL device including an organic light emitting diode, an inorganic light emitting diode, or a quantum dot light-emitting diode.

8. A controller configured to control the manufacturing apparatus for an EL device according to claim 7 comprising:
a control circuit provided to allow the main rotating member to rotate around the main rotating shaft provided on the first end side of the evaporation mask to face the support member across the evaporation mask.

9. A manufacturing method for an EL device, the method using a manufacturing apparatus for the EL device comprising:
a first clamping member configured to clamp a first end of an evaporation mask placed on a substrate to form an evaporation layer for the EL device; and
a second clamping member configured to clamp a second end of the evaporation mask,
the first clamping member including a support member configured to support a first surface of the evaporation mask,
the method comprising:
rotating a main rotating member around a main rotating shaft provided on a side of the first end of the evaporation mask to face the support member across the evaporation mask; and
rotating an auxiliary rotating member around an auxiliary rotating shaft of the main rotating member to come into surface-contact with a second surface of the evaporation mask,
the EL device including an organic light emitting diode, an inorganic light emitting diode, or a quantum dot light-emitting diode.
